(19) United States
(12) Patent Application Publication
(10) Pub. No.: US 2004/0263024 A1
(43) Pub. Date: Dec. 30, 2004

(54) Piezodynamic preload adjustment system

(76) Inventors: Marc E. Meffe, Glendale, AZ (US); Jack H. Jacobs, Glendale, AZ (US); Richard A. Hightower, Peoria, AZ (US)

Correspondence Address: HONEYWELL INTERNATIONAL INC., 101 COLUMBIA ROAD, P O BOX 2245, MORRISTOWN, NJ, 07962-2245, US

(21) Appl. No.: 10/608,176

(22) Filed: Jun. 26, 2003

(51) Int. Cl. H01L 41/08

(52) U.S. Cl. 310/314

(57) ABSTRACT

A preload adjustment device and method are provided for momentum control devices. The preload adjustment device includes a piezodynamic preload spacer and a control system. The piezodynamic preload spacer is coupled to a bearing in the momentum control device. The piezodynamic preload spacer is configured such that the application of a control voltage to spacer causes a change in the spacer dimensions, with that change in spacer dimension adjusting the preload of the bearing within the momentum control device. The control system provides dynamic control of preload by selective application of control voltage to the piezodynamic preload spacer. This allows for adjustments of preload to compensate for changes in operating environment, improving the performance of the momentum control device. Additionally, adjustments of preload can by used to compensate for wear in the bearings that would otherwise negatively impact the life of the momentum control device. In an additional embodiment, the preload adjustment device is used to change preload at a high frequency rate. This high frequency change in preload provides vibrations to the bearing that can facilitate the even distribution of lubrication within the bearing, improving the performance of the bearing.

### FIELD OF THE INVENTION

This invention generally relates to momentum control devices, and more specifically applies to bearings in momentum control devices in spacecraft.

### BACKGROUND OF THE INVENTION

Various types of momentum control devices are commonly used to provide attitude control to spacecraft and other vehicles. These momentum control devices are used to provide a torque on the vehicle for attitude control and other purposes. Examples of momentum control devices include reaction wheels and control moment gyroscopes.

Reaction wheels are commonly used to provide attitude and momentum control for a variety of vehicles. Reaction wheels typically comprise a rotor, bearings and motor, with the reaction wheel coupled to the vehicle structure. The motor provides the ability to vary the wheel speed of the rotor. As the rotor speed is varied, a momentum exchange occurs and the motor provides a torque on the vehicle about the spin axis. In most applications, multiple reaction wheels are used in a reaction wheel array. The multiple reaction wheels in the array are arranged so that their spin axes span three dimensions for three axis control. Arranging the multiple reaction wheels in this way allows the array to apply torque to the vehicle along different axes, generally all three. Torque can be selectively applied to these axes to provide attitude control of the vehicle.

Similarly, control moment gyroscopes are commonly used to provide attitude and momentum control for a variety of vehicles, including spacecraft and satellites. Control moment gyroscopes normally comprise a rotor and a motor to spin the rotor about a rotor axis. The rotor is typically supported in an inner gimbal assembly and is rotated about a gimbal axis using a gimbal torque motor assembly that is attached to one end of the gyroscope. A sensor module assembly is attached to the other end of the gyroscope and is used to sense the rotational position of the inner gimbal assembly about the gimbal axis to provide for control of rotation. The control moment gyroscope is mounted within the vehicle along the axis in which it will induce a torque. During operation of the gyroscope, the rotor is spun by a motor about its rotor axis at a predetermined rate. In order to induce a torque on the spacecraft, the gimbal torque motor rotates the gimbal assembly and the spinning rotor about the gimbal axis. The rotor is of sufficient mass and is spinning at such a rate that any movement of the rotor out of its plane of rotation will induce a significant torque around an output axis that is both normal to the rotor axis and the gimbal axis. This torque is transferred to the vehicle, causing the vehicle to move in a controlled manner.

While traditional momentum control devices such as reaction wheels and control moment gyroscopes are generally effective, they suffer from some performance and reliability limitations. As stated above, both reaction wheels and control moment gyroscopes use rotors that must reliably spin at high rates of rotation for very long periods of time. To facilitate this, these rotors are affixed to the momentum control device using precision bearings that allow the rotor to rotate around the shaft. Because of the high rates of speed involved and the reliability required, the performance of these bearings is of particular importance. Unfortunately, the reliability and performance of these bearings has been limited in some cases by the inability to accurately control bearing preload. Bearing preload determines the amount of contact between the bearing balls and the bearing ball races. Without proper bearing preload, the performance and reliability of the bearing is limited.

Thus, what is needed is an improved system and method for setting and adjusting the bearing preload in a momentum control device.

### BRIEF SUMMARY OF THE INVENTION

The present invention provides a preload adjustment device and method for momentum control devices. The preload adjustment device includes a piezodynamic preload spacer and a control system. The piezodynamic preload spacer is coupled to a bearing in the momentum control device. The piezodynamic preload spacer is configured such that the application of a control voltage to spacer causes a change in the spacer dimensions, with that change in spacer dimension adjusting the preload of the bearing within the momentum control device. The control system provides dynamic control of preload by selective application of control voltage to the piezodynamic preload spacer.

Thus, the preload adjustment device can accurately control preload of a bearing in a momentum control device. This allows for adjustments of preload to compensate for changes in operating environment, improving the performance of the momentum control device. Additionally, adjustments of preload can by used to compensate for wear in the bearings that would otherwise negatively impact the life of the momentum control device.

In an additional embodiment, the preload adjustment device is used to change preload at a high frequency rate. This high frequency change in preload provides vibrations to the bearing that can facilitate the even distribution of lubrication within the bearing, improving the performance of the bearing.

The foregoing and other objects, features and advantages of the invention will be apparent from the following more particular description of a preferred embodiment of the invention, as illustrated in the accompanying drawings.

### BRIEF DESCRIPTION OF DRAWINGS

The preferred exemplary embodiment of the present invention will hereinafter be described in conjunction with the appended drawings, where like designations denote like elements, and:

FIG. 1 is a schematic view a preload adjustment device;

FIG. 2 is a cross-sectional schematic view a reaction wheel assembly;

FIG. 3 is a cross-sectional view of a momentum control device bearing with piezodynamic preload spacer;

FIG. 4 is a perspective view of a piezodynamic preload spacer;

FIG. 5 is a cross-sectional view of a single momentum control device bearing with piezodynamic preload spacer; and

FIG. 6 is a schematic view of a control system.

### DETAILED DESCRIPTION OF THE INVENTION

The present invention provides a preload adjustment device and method for momentum control devices. The preload adjustment device includes a piezodynamic preload spacer and a control system. The piezodynamic preload spacer is coupled to a bearing in the momentum control device. The piezodynamic preload spacer is configured such that the application of a control voltage to spacer causes a change in the spacer dimensions, with that change in spacer dimension adjusting the preload of the bearing within the momentum control device. The control system provides dynamic control of preload by selective application of control voltage to the piezodynamic preload spacer.

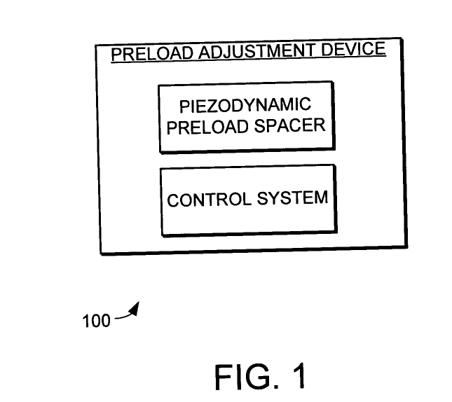

Turning now to FIG. 1, a schematic view of a preload adjustment device 100 is illustrated. The preload adjustment device 100 can be used to adjust the bearing preload in momentum control devices such as reaction wheel assemblies (RWAs) and control moment gyroscopes (CMGs). The preload adjustment device 100 includes a piezodynamic preload spacer and a control system. The piezodynamic preload spacer is coupled to at least one bearing in the momentum control device, configured such that a change in a dimension of the piezodynamic preload spacer adjusts the preload on the at least one bearing. The control system provides a control voltage that is used to control the piezodynamic preload spacer. The control system thus provides the ability to control preload on the bearing by selectively providing the control voltage. The control system can adjust preload to provide optimal preload in a variety of circumstances. For example, the control system can adjust preload to increase the performance of the bearings. Likewise, the control system can adjust preload to compensate for changes in the operational environment of the momentum control device. As a third example, the control system can adjust preload to compensate for wear in the bearings. It should be noted that while FIG. 1 illustrates the control system and the piezodynamic preload spacer together, in fact these two elements of the preload adjustment device can be implemented in completely separate locations.

In a further variation on this example, the control system can adjust preload at a high frequency rate. A periodic, high frequency change in preload can be used to provide controllable vibrations to the bearings in the momentum control device. These controllable vibrations can be used to facilitate the even distribution of lubrication within the bearings, and thus improve the performance of the bearings in the momentum control device.

In this application, the term “preload” refers to a predefined stress imposed on one or more bearings such that the contact angle between bearing balls and bearing races is set to a given contact angle. The preload of a bearing determines the clearance between the balls and races of the bearings. A proper preload on the bearings assures that the balls within the bearing are positioned to ride at the correct contact angle within the race. Generally, preload is established on bearings by applying force to the outer races. As preload is increased, more contact is established between the balls and the races, and more stiffness is added to the shaft.

In current momentum control devices, preload of the bearings is set during the manufacture of the bearings and or device and may not be actively modified thereafter. As such, bearing preload is typically set to the minimum value required for the worst case condition. This assures that sufficient preload exists in all situations, but it does not allow for optimization of the preload. For example, the preload can be set to a value that allows the momentum control device to be safely tested on the ground. Such a preload setting would not typically be ideal for operating in a zero gravity environment such as space. Likewise, preload may need to be set high enough to protect the momentum device from the high gravities and vibrations that occur during a space launch. Such a high preload would commonly be higher than is desirable operation of the momentum control device in space.

The preload adjustment device 100 can be used adjust the preload of the bearings to more effectively optimize the performance of the bearings. Thus, the preload adjustment device can be used increase bearing preload during on the ground testing or launch, and to provide reduced preload when the momentum control device is operated in space. Thus, the preload adjustment device 100 can be used to optimize the preload for a variety of operating conditions.

In another application, the bearing preload can be increased to provide increased stability during certain operations. For example, in a control moment gyroscope, the bearing preload can be increased to provide improved rotor stability when there is a high applied radial load on the bearings caused by a gimballing.

Additionally, the preload adjustment device 100 can be used to compensate for wear in the bearings. As bearings are used, the balls and races typically wear away. This wear gradually changes the preload of the bearing. Again, bearings have typically been manufactured with increased preload to compensate for the inevitable decline in preload caused by wear. This results in the bearing initially operating at a less than ideal preload. The preload adjustment device 100 can be used to increase preload as the bearings wear, thus eliminating the need for the increased preload at manufacturing. This again can improve the performance of the bearings throughout their life.

Finally, the bearings can be adjusted over temperature extremes to account for material differences in the bearings. In some bearings, different parts of the bearings may be made of different materials with different coefficients of thermal expansion. In such bearings, changes in temperature may change preload. The preload adjustment device can be used to compensate for such temperature induced changes in preload.

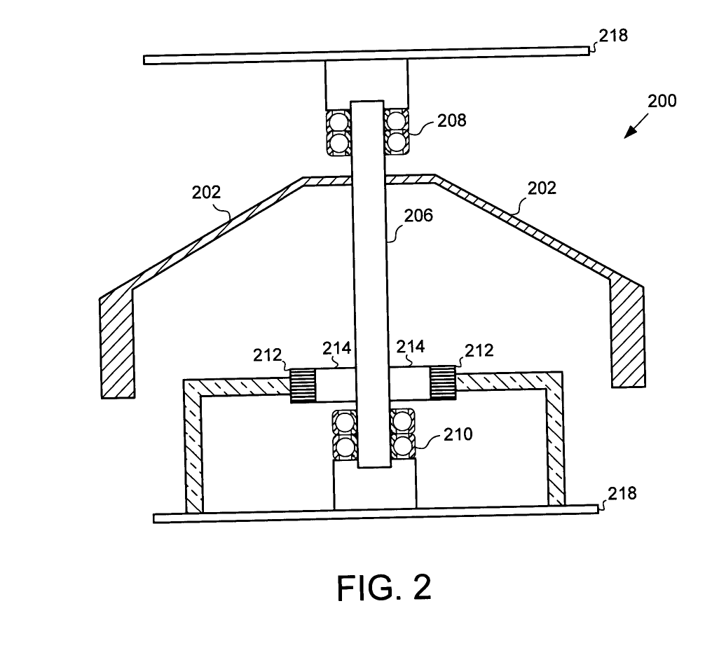

Turning now to FIG. 2, a cross-sectional view of a reaction wheel assembly 200 is illustrated. Reaction wheel assembly 200 illustrates one type of momentum control device in which the piezodynamic preload device can be utilized. Other applications of piezodynamic preload device include other momentum control devices, such as control moment gyroscopes.

The reaction wheel assembly includes a rotor 202 coupled to a shaft 206. The shaft 206 rotates on bearings 208 and 210, and is driven by a motor that comprises a motor stator 212 and a motor rotor 214. The motor stator 212 is attached to a reaction wheel structure 216, which is attached to the vehicle through a base 218.

In operation, the motor stator 212 and motor rotor 214 rotates the shaft 206, causing the rotor 202 to rotate and impart a torque on the vehicle through the reaction wheel structure 216 and base 218. It should be noted that the reaction wheel assembly 200 is just one example of the type of reaction wheel assembly in which the preload adjustment device can be implemented. Many other reaction wheels may be suitable for modification. For example, of suitable reaction wheels include the HR0610 and HR14 available from Honeywell International, Inc. Other examples of reaction wheel designs can be found at U.S. Pat. No. 5,873,285 issued to Barnes and assigned to Honeywell International, Inc.

As stated above, the reaction wheel shaft 205 and rotor 202 rotate on bearings 208 and 210. Because the rotor 202 must reliably spin at high rates of rotation for very long periods of time the bearings 208 and 210 are preferably high performance, precision bearings. In the example of reaction wheel 200, the bearings 208 and 210 are duplex bearings, meaning each bearing comprises a set of two bearings adjacent to each other. Other reaction wheel designs and other momentum control devices may use single sets of bearings. In either case, the preload adjustment device can be used to adjust the preload of the bearings to improve performance of the bearings. Additionally, the preload adjustment device 100 can be used for other types of bearings in momentum control devices, including single bearings or so called “simplex” bearings.

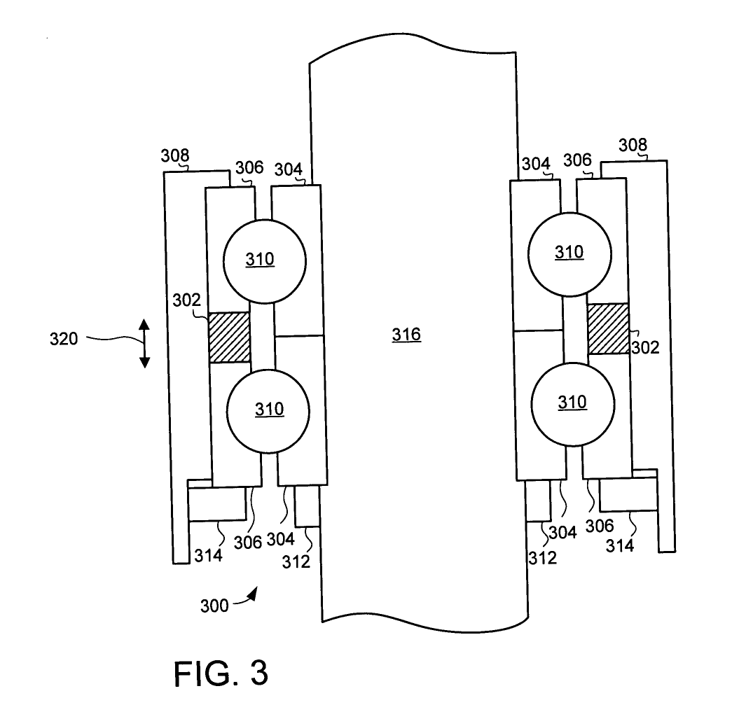

Turning now to FIG. 3, cross-sectional view of an exemplary bearing 300 that includes a piezodynamic preload spacer 302 is illustrated. Bearing 300 comprises a duplex bearing, meaning that two bearings are used together. Again, this is just one type of bearing that can be used in a momentum control device. Bearing 300 rotates about a shaft 316 and includes inner races 304, outer races 306, a bearing cartridge 308, balls 310, a shaft nut 312, and a preload nut 314. In general, the preload nut determines the static preload, the preload that is provided without the expansion or contraction of the piezodynamic preload spacer. The bearing 300 is coupled to the piezodynamic preload spacer 302 in a way that application of a control voltage to piezodynamic spacer causes a change in the spacer dimensions, with that change in spacer dimension adjusting the preload of the bearing within the momentum control device.

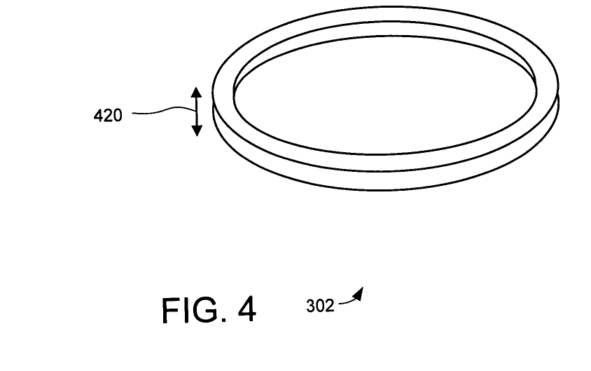

In the illustrated example, the piezodynamic preload spacer comprises 302 a ring that encircles the outer portion of the bearings. Turning briefly to FIG. 4, a perspective view of the complete piezodynamic preload spacer 302 is illustrated. The piezodynamic preload spacer 302 is configured as a ring or torroid, such that the control voltage can be used to adjust the thickness of the ring, as illustrated by direction line 420. Of course, this is just one possible configuration for the piezodynamic preload spacer 302. Other potentially suitable shapes include partial torroids.

Returning again to FIG. 3, in the illustrated example, the piezodynamic preload spacer 302 is located between the outer races 306. Of course, this is just one way in which the piezodynamic preload spacer 302 can be coupled to the bearings. The piezodynamic preload spacer 302 can expand and contract in thickness, in the direction illustrated by line 320. Expanding and contracting in this way changes the preload on the bearings 300. For example, expanding in thickness out in the direction illustrated in by line 308 would increase the preload on the bearings. Conversely, shrinking in thickness dimension would reduce the preload on the bearings.

It should also be noted that while the example of FIG. 3 shows a case where an expansion of the spacer increases the preload, in other configurations the preload spacer could be implemented such that an increase in spacer thickness reduces preload on the bearings.

As stated above, this is just one example of how a piezodynamic preload spacer can be configured. In other examples, the piezodynamic preload spacer is coupled indirectly to the bearings, such that the piezodynamic preload spacer provides preload to the bearings through some other intermediate member. Also, instead of being between a duplex pair of bearings, the preload spacer could be configured at the edge of one or more bearings.

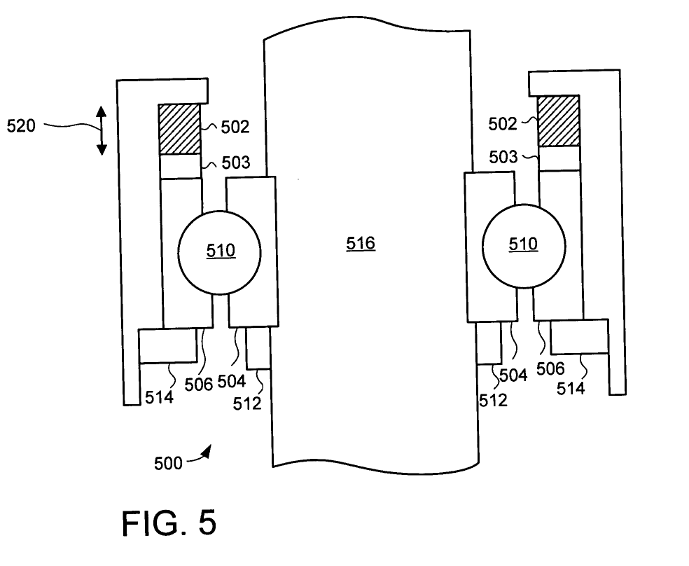

Turning now to FIG. 5, cross-sectional view of an exemplary single bearing 500 that includes a piezodynamic preload spacer 502 coupled through an intermediate member is illustrated. Again, this is just another type of bearing that can be used in a momentum control device. Bearing 500 rotates about a shaft 516 and includes an inner race 504, outer race 506, a bearing cartridge 508, balls 510, a shaft nut 512, and a preload nut 514. The bearing 500 is coupled to the piezodynamic preload spacer 502 in a way that application of a control voltage to piezodynamic spacer causes a change in the spacer dimensions, with that change in spacer dimension adjusting the preload of the bearing within the momentum control device.

In this illustrated example, the piezodynamic preload spacer comprises 502 is coupled to the bearing through an intermediate member 502. Again, this is just one way in which the piezodynamic preload spacer 502 can be coupled to a bearing through an intermediate member. The piezodynamic preload spacer 502 can expand and contract in thickness, in the direction illustrated by line 508. Expanding and contracting in this way provides a force on the intermediate member 502, which in turn changes the preload on the bearings 500. For example, expanding in thickness out in the direction illustrated in by line 508 would increase the preload on the bearings. Conversely, shrinking in thickness dimension would reduce the preload on the bearings.

The piezodynamic preload spacer in these embodiments can be configured such that its static dimension, i.e., the dimension with no voltage applied, results in optimal operational preload. This would allow the momentum control device to conserve power, as power would only be consumed by the preload adjustment device for relatively infrequent situations where increased preload as needed. For example, the piezodynamic preload spacer can be configured such that its static dimension provides the correct operational preload for the bearings while the momentum control device operates in the zero gravity of space. When the bearings require more preload, such as during the on the ground testing or during launch, voltage can be applied to the piezodynamic preload spacer to expand (or contract) the spacer and increase the preload to meet the preload requirements under this condition. Again, this is just one example, and the piezodynamic preload spacer could be configured.

The piezodynamic preload spacer can be made from any suitable piezodynamic material or combination of electrically controllable materials. As used in this specification, piezodynamic materials are those materials such as piezoelectric or electrostrictive materials that mechanically deform when an external electric field is applied. These can take the form of single crystal layers or multi-layered stacks to reduce overall power consumption. Several types of piezodynamic materials are available commercially that could be applied to this application such as PZT, PMN, PLZT, etc. Each material formulation can either be layered into stacks to obtain a spacer structure with either polymer binder or a co-firing process for additional strength using existing manufacturing processes.

The piezodynamic preload spacer is configured such that a change in control voltage adjusts the preload of the bearings in the momentum control device. This configuration can include the polling of piezodynamic materials. For example, the piezodynamic material can be polled in a D₃₁ configuration, where adding an electric field in a third dimension causes a mechanical deformation in a first dimension. As another example, the piezodynamic material call be polled in a D₁₁ configuration, where adding an electric field in the first dimension causes a mechanical deformation in the first dimension. In either case, the piezodynamic preload spacer would be coupled to the bearing and electrically connected such that the change in control voltage changes a physical dimension that adjusts the preload of the bearings in the momentum control device.

As stated above, the piezodynamic preload spacer can be coupled to the bearings in a variety of ways. As illustrated in FIG. 3, the piezodynamic preload spacer can be located adjacent to one or more bearings in such a way that a change in spacer dimension changes bearing preload. Likewise, as illustrated in FIG. 5, the piezodynamic preload spacer can be coupled to the bearing through an intermediate member such that a change in dimension of the spacer is transferred through the intermediate member to result in a bearing preload change.

In some applications it will be desirable to bond the piezodynamic preload spacer to the bearing or the intermediate member. This will allow the piezodynamic preload spacer to adjust preload by “pulling” at intermediate member and/or the bearing. Such a bond can be made with any electrical, mechanical or chemical fastener. Such a configuration could allow an increase in preload to be achieved by a reduction in piezodynamic preload spacer dimension.

It should also be noted that it will be desirable in many cases to provide a fail-safe configuration, designed such that a failure of the piezodynamic preload spacer or control system will result in a sufficient preload to maintain operation. Thus, the momentum control device may continue to operate, although at potentially less efficiency, even when the preload adjust device has failed unexpectedly. This could be done such that the baseline preload is achieved when the preload spacer is in the unexcited state and that the reduced or increased preload is achieved with the spacer in an excited state.

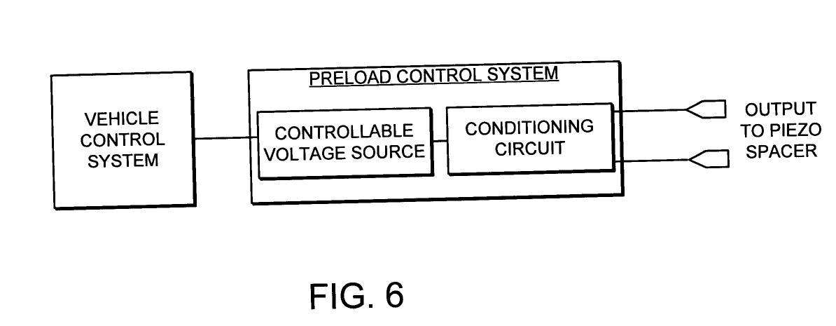

Turning now to FIG. 6, an exemplary preload control system is illustrated schematically. The exemplary preload control system includes a controllable voltage source and a conditioning circuit. The preload control system receives control information from the vehicle system and provides a control voltage to the piezodynamic preload spacer. This allows the control system of the vehicle to control the preload of the bearings in the momentum control device. Such preload control can be done by traditional control systems, vehicle health management systems, or under the control of operators and/or ground control. Typically, the system would monitor the performance of the momentum control device and adjust the preload accordingly. As described above, this can include adjusting to optimize the bearing preload, to account for changes in operating environment, to account for wear in the bearings, and/or to improve the distribution of lubricant throughout the bearing.

The controllable voltage source provides a control signal of appropriate frequency and shape that is used to adjust the preload. This control signal is then set at the appropriate level in the conditioning circuit, with the conditioning circuit then outputting a control voltage to the piezodynamic spacer that has the appropriate frequency, shape and level. The functionality of the controllable voltage source and conditioning circuit can be implemented with any suitable device, system or method. This can include complex hardware and/or software implementations, as well as relatively simple circuit designs. Furthermore, the functionality of the controllable voltage source and conditioning circuit can be implemented in separate devices, or together as part of one overall device.

The frequency, shape and voltage level of the control voltage provided to the piezodynamic preload spacer would depend upon the type, configuration of piezodynamic material used, and the desired preload. It should also be noted that for some piezodynamic materials it will be desirable to vary control voltage levels to keep the piezodynamic material holding a desired dimension. Otherwise, some types of piezodynamic materials will lose the ability to change and/or maintain desired dimension.

The field strength and voltage level applied to the piezodynamic preload spacer would be dependent on the stack configuration and material type chosen for a preload spacer. Hence, the conditioning circuit would preferably be tunable to accommodate varying types of physical implementations of the spacer. Voltages would typically range from between 50 and 300 volts, and currents would typically range from a few milliamps to 100's of milliamps, depending on the spacer material construction. The conditioning circuit is preferably designed to insure that the conversion from the on-board voltage source to the piezodynamic preload spacer is performed to maximize the displacement of the spacer while minimizing power consumption. The conditioning circuit also preferably takes into account the slow decay times of the piezodynamic material so a relatively constant pre-load can be achieved at near zero frequency.

In most cases, changes to the bearing preload are needed relatively infrequently. In these cases, the control voltage will usually change slowly as changes in preload are needed. However, in some circumstances it may be desirable to rapidly change preload to improve the performance of the device. One such circumstance is cases where lubrication within the bearing needs to be redistributed.

Bearings are commonly filled with a lubricant such as grease to improve the performance and reliability of the bearings. One issue in use of lubricants is the propensity of lubrication to fall back into the bearings and cause torque spikes. Typically, the torque spikes caused by lubrication are small, but they can impact performance. Additionally, such torque spikes can last for months until the lubricant distributes itself back through the bearings. The piezodynamic preload spacer can be used to facilitate lubrication distribution. This would typically be done by rapidly adjusting the preload of the bearing during operation.

By providing an appropriate high frequency control signal, the piezodynamic preload spacer can be made to provide the high frequency vibration that will more quickly redistribute the lubrication. Such high frequency vibration can be on the order of several thousand cycles per second, although the frequency chosen would typically depend on the configuration of the bearings.

As discussed above, the conditioning circuit preferably accounts for variances in the piezodynamic material construction. In addition, for high frequency applications such as grease distribution, the conditioning circuit should be able to regulate the controllable voltage source to precise levels or may sweep the frequency range to properly distribute the grease depending on the feedback from the vehicle control system.

The present invention thus provides a preload adjustment device and method for momentum control devices. The preload adjustment device includes a piezodynamic preload spacer and a control system. The piezodynamic preload spacer is coupled to a bearing in the momentum control device. The piezodynamic preload spacer is configured such that the application of a control voltage to spacer causes a change in the spacer dimensions, with that change in spacer dimension adjusting the preload of the bearing within the momentum control device. The control system provides dynamic control of preload by selective application of control voltage to the piezodynamic preload spacer. Thus, the preload adjustment device can accurately control preload of a bearing in a momentum control device. This allows for adjustments of preload to compensate for changes in operating environment, improving the performance of the momentum control device. Additionally, adjustments of preload can by used to compensate for wear in the bearings that would otherwise negatively impact the life of the momentum control device. In an additional embodiment, the preload adjustment device is used to change preload at a high frequency rate. This high frequency change in preload provides vibrations to the bearing that can facilitate the even distribution of lubrication within the bearing, improving the performance of the bearing.

The embodiments and examples set forth herein were presented in order to best explain the present invention and its particular application and to thereby enable those skilled in the art to make and use the invention. However, those skilled in the art will recognize that the foregoing description and examples have been presented for the purposes of illustration and example only. The description as set forth is not intended to be exhaustive or to limit the invention to the precise form disclosed. Many modifications and variations are possible in light of the above teaching without departing from the spirit of the forthcoming claims.

1. A preload adjustment device, the preload adjustment device comprising:
a) a piezodynamic preload spacer, the piezodynamic preload spacer coupled to a bearing in a momentum control device, the piezodynamic preload spacer configured such that an application of a control voltage to the piezodynamic preload spacer causes a change in a dimension of the piezodynamic preload spacer, and wherein the piezodynamic preload spacer is configured such that a change in the dimension of the piezodynamic preload spacer changes a preload of the bearing; and
b) a control system, the control system providing selective control of the control voltage to selectively control the preload on the bearing.

2. The preload adjustment device of claim 1 wherein the piezodynamic preload spacer is located adjacent the bearing.

3. The preload adjustment device of claim 1 wherein the bearing comprises a duplex bearing pair and wherein piezodynamic preload spacer is located between the duplex bearing pair.

4. The preload adjustment device of claim 1 wherein piezodynamic preload spacer comprises a ring shaped spacer having a thickness, and wherein the application of the control voltage to the piezodynamic preload spacer causes a change in thickness.

5. The preload adjustment device of claim 1 wherein the piezodynamic preload spacer comprises a piezoelectric material.

6. The preload adjustment device of claim 1 wherein the piezodynamic preload spacer is coupled to the bearing through an intermediate member.

7. The preload adjustment device of claim 1 wherein the momentum control device comprises a reaction wheel.

8. The preload adjustment device of claim 1 wherein the momentum control device comprises a control moment gyroscope.

9. The preload adjustment device of claim 1 wherein the control system provides selective control of the control voltage to control the preload to compensate for changes in operating environment.

10. The preload adjustment device of claim 1 wherein the control system provides selective control of the control voltage to control the preload to compensate for wear in the bearing.

11. The preload adjustment device of claim 1 wherein the control system provides selective control of the control voltage to control the preload to compensate for thermal expansion in the bearing.

12. The preload adjustment device of claim 1 wherein the control system provides selective control of the control voltage to distribute lubrication in the bearing.

13. The preload adjustment device of claim 12 wherein the control system provides a varying control voltage to distribute the lubrication in the bearing.

14. The preload adjustment device of claim 1 wherein the control system increases preload during a launch of the momentum control device into space.

15. The preload adjustment device of claim 1 wherein the piezodynamic preload spacer is configured to provide a reduced preload with a low control voltage and an increased preload with a high control voltage.

16. The preload adjustment device of claim 15 wherein the reduced preload comprises an optimal operating preload.

17. A preload adjustment device for adjusting preload in a duplex bearing in a momentum control device, the duplex bearing including a first bearing race and a second bearing race, the preload adjustment device comprising:
a) a piezodynamic preload spacer, the piezodynamic preload spacer coupled between the first bearing race and the second bearing race, the piezodynamic preload spacer configured such that an application of a control voltage to the piezodynamic preload spacer causes a change in a dimension of the piezodynamic preload spacer, and wherein the piezodynamic preload spacer is configured such that a change in the dimension of the piezodynamic preload spacer changes the preload of the duplex bearing; and
b) a control system, the control system providing selective control of the control voltage to selectively control the preload on the bearing.

18. The preload adjustment device of claim 17 wherein piezodynamic preload spacer comprises a ring shaped spacer having a thickness, and wherein the application of the control voltage to the piezodynamic preload spacer causes a change in thickness.

19. The preload adjustment device of claim 17 wherein the control system provides selective control of the control voltage to control the preload to compensate for changes in operating environment.

20. The preload adjustment device of claim 17 wherein the control system provides selective control of the control voltage to control the preload to compensate for wear in the bearing.

21. The preload adjustment device of claim 17 wherein the control system provides selective control of the control voltage to control the preload to compensate for thermal expansion in the bearing.

22. The preload adjustment device of claim 17 wherein the control system provides a varying of the control voltage to distribute lubrication in the bearing.

23. The preload adjustment device of claim 17 wherein the control system increases preload during a launch of the momentum control device into space.

24. The preload adjustment device of claim 17 wherein the piezodynamic preload spacer is configured to provide an optimal operating preload for operating in space with a low control voltage and an increased preload with a high control voltage.

25. A lubrication distribution device for distributing lubrication in a bearing in a momentum control device, the lubrication distribution device comprising:
a) a piezodynamic spacer, the piezodynamic spacer coupled to the bearing in the momentum control device, the piezodynamic spacer configured such that an application of a control voltage to the piezodynamic spacer causes a change in a dimension of the piezodynamic spacer, and wherein the piezodynamic spacer is configured such that a change in the dimension of the piezodynamic spacer changes exerts a force on the bearing; and
b) a control system, the control system varying the control voltage to provide a periodic force on the bearing and distribute lubrication in the bearing.

26. The lubrication distribution device of claim 25 wherein the piezodynamic spacer exerts a force on the bearing that that changes a preload on the bearing.
